(19) United States
(12) Patent Application Publication
(10) Pub. No.: US 2026/0168101 A1
(43) Pub. Date: Jun. 18, 2026

(54) LOAD LOCK ARRANGEMENT COMPRISING A MICROWAVE HEATER FOR DESORBING MOISTURE AND SUBSTRATE PROCESSING APPARATUS

(71) Applicant: ASM IP Holding B.V., Almere (NL)

(72) Inventors: Salam Harb, Scottsdale, AZ (US); Samer Banna, Phoenix, AZ (US)

(21) Appl. No.: 19/417,623

(22) Filed: Dec. 12, 2025

Related U.S. Application Data
(60) Provisional application No. 63/735,064, filed on Dec. 17, 2024.

(51) Int. Cl. C23C 16/458; C23C 16/455; C23C 16/46; H10P 72/00

(52) U.S. Cl. CPC C23C 16/4585; C23C 16/45544; C23C 16/46; H10P 72/0466

(57) ABSTRACT

This disclosure relates to a load lock arrangement and a substrate processing apparatus comprising the load lock arrangement. The load lock arrangement comprises a load lock chamber body that defines a load lock chamber, a substrate holder for holding one or more substrates in the load lock chamber, and a microwave heater for desorbing adsorbed moisture from the one or more substrates.

### CROSS-REFERENCE TO RELATED APPLICATIONS

This application claims priority to U.S. Provisional Patent Application Ser. No. 63/735,064 filed Dec. 17, 2024 titled LOAD LOCK ARRANGEMENT COMPRISING A MICROWAVE HEATER FOR DESORBING MOISTURE AND SUBSTRATE PROCESSING APPARATUS, the disclosure of which is hereby incorporated by reference in its entirety.

### TECHNICAL FIELD

This disclosure generally relates to the fields of microfabrication and nanofabrication. In particular, the present disclosure relates to the field of semiconductor manufacturing technology, for example, the fabrication of integrated circuits.

### BACKGROUND

There is continuing interest in improving the efficiency and quality of thin film deposition in semiconductor manufacturing. It is generally accepted that moisture adsorption onto incoming wafers can significantly affect the film deposition quality of process tools. Moisture on wafer surfaces can, for example, prevent good adhesion during film deposition and increase the risk of oxidation and poor resistivity performance on metal films. Monolayers of moisture can easily accumulate on wafer surfaces during transportation from a Front Opening Unified Pod (FOUP) to a load lock vacuum chamber if the wafer passes through an air-flown environment inside an Equipment Front End Module (EFEM) space.

However, conventional solutions for wafer degassing, such as conductive, convection, and infrared radiation methods, are time-consuming and occupy valuable space that could otherwise be used for wafer processing. Despite the importance of efficient moisture desorption, limited innovation has been focused on addressing these challenges. In light of the above, it may be desirable to develop novel solutions related to enhancing moisture desorption efficiency in semiconductor manufacturing tools.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

According to a first aspect, a load lock arrangement is provided. The load lock arrangement comprises a load lock chamber body that defines a load lock chamber and comprises a first face configured for coupling to a transfer module and a second face configured for coupling to a vacuum chamber. The load lock arrangement further comprises a substrate holder for holding one or more substrates in the load lock chamber and a microwave heater for desorbing adsorbed moisture from the one or more substrates.

According to a second aspect, a substrate processing apparatus comprising a load lock arrangement in accordance with the first aspect is provided.

In some embodiments, the load lock chamber body comprises a viewport, and the microwave heater is configured to transmit microwave radiation into the load lock chamber via the viewport.

In some embodiments, the microwave heater comprises a magnetron microwave source.

In some embodiments, the microwave heater comprises a microwave mode stirrer.

In some embodiments, the microwave heater is configured to generate microwave radiation within a wavelength range from 1 cm to 30 cm, or from 3 cm to 25, or from 5 cm to 20 cm, or from 10 cm to 15 cm, or from 11 cm to 13 cm.

In some embodiments, the microwave heater is configured to generate microwave radiation at a microwave output power greater than or equal to 25 W, or to 50 W, or to 100 W, or to 200 W, or to 500 W, or to 1 kW and/or less than or equal to 2 kW, or to 3 kW, or to 4 kW, or to 5 kW, or to 10 kW.

In some embodiments, the load lock chamber body comprises one or more evacuation ports for evacuation of the load lock chamber.

In some embodiments, the load lock chamber body further defines a second load lock chamber for substrate transfer between the transfer module and the vacuum chamber.

In some embodiments, the substrate holder is configured to hold the one or more substrates in a stacked arrangement at a plurality of substrate positions, maintaining a minimum distance between adjacent substrate positions of the plurality of substrate positions of at least 1 cm, or at least 2 cm, or at least, 3 cm, or at least 4 cm, or at least 5 cm, or at least 6 cm, or at least 7 cm, or at least 8 cm, or at least 9 cm, or at least 10 cm, or at least 11 cm, or at least 12 cm.

In some embodiments, the load lock arrangement is configured to accommodate at most two substrates in the load lock chamber.

In some embodiments, the load lock arrangement is configured to accommodate at most one substrate in the load lock chamber.

In some embodiments, the substrate processing apparatus comprises a transfer module coupled to the load lock arrangement.

In some embodiments, the substrate processing apparatus comprises a vacuum chamber coupled to the load lock arrangement.

In some embodiments, the substrate processing apparatus comprises a vacuum pump fluidically coupled to the load lock chamber for evacuation thereof.

In some embodiments, the substrate processing apparatus comprises one or more deposition chambers coupled to the vacuum chamber.

### DESCRIPTION OF THE DRAWINGS

A more complete understanding of the embodiments of the present disclosure may be derived by referring to the detailed description and claims when considered in connection with the following illustrative figures:

FIG. 1 illustrates a substrate processing apparatus and a load lock arrangement, and

FIG. 2 shows another load lock arrangement.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

The illustrations presented herein are not meant to be actual views of any particular material, structure, or device, but are merely idealized representations that are used to describe embodiments of the disclosure.

For clarity and brevity, consistent reference numerals may be used throughout the figures for corresponding, similar, and/or identical elements.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail or omitted entirely. Furthermore, the connecting lines shown in the various figures are intended to represent example functional relationships and/or physical couplings between the various elements. Many alternative or additional functional relationship or physical connections may be present in the practical system, and/or may be absent in some embodiments.

It is to be understood that the configurations and/or approaches described herein are examples in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

Throughout this specification, a “chamber” may refer to an enclosed space suitable or configured for containing and/or processing one or more substrates. Additionally or alternatively, a chamber may refer to an enclosed space suitable or configured for containing and/or processing one or more substrates under controlled conditions. Additionally or alternatively, a chamber may refer to an enclosed space suitable or configured for isolation from the external environment to maintain specific environmental conditions, such as pressure, temperature, and/or gas composition. In some embodiments, a chamber may refer to an interior cavity defined by outer walls and/or by one or more doors or ports for allowing substrates to enter and/or exit said cavity.

In this disclosure, a “load lock chamber” may refer to a chamber suitable or configured for transferring substrates between different environments, for example, between a high-vacuum environment and an atmospheric or low-vacuum environment. Additionally or alternatively, a load lock chamber may refer to a chamber suitable or configured for loading and/or unloading substrates into and/or out of a processing chamber. Additionally or alternatively, a load lock chamber may refer to a chamber suitable or configured to account for pressure differences between different environments during the transfer of substrates. Additionally or alternatively, a load lock chamber may refer to a chamber suitable or configured for isolating its interior from the external environment to maintain specific environmental conditions, such as pressure, temperature, and/or gas composition, during the transfer of substrates.

In this specification, a “load lock chamber body” may refer to a structure forming the outer walls of a load lock chamber. Additionally or alternatively, a load lock chamber body may refer to a structure that provides mechanical support and/or fluid isolation for a load lock chamber. In some embodiments, a load lock chamber body may comprise one or more materials suitable for maintaining the structural integrity and/or environmental isolation of a load lock chamber. Such materials may include, but are not limited to, metals, such as stainless steel or aluminum, and quartz. In some embodiments, a load lock chamber body may include one or more ports or openings for the installation of pumps, valves, sensors, and/or other components necessary or beneficial for the operation of the load lock chamber. In some embodiments, a load lock chamber body may be designed to withstand various environmental conditions, such as vacuum, elevated temperatures, and/or exposure to reactive gases. In some embodiments, a load lock chamber body may be integrated with one or more structural supports, such as frames or brackets, to provide additional mechanical stability.

Throughput this disclosure, “vacuum” may refer to an environment with significantly reduced pressure compared to atmospheric pressure. Additionally or alternatively, vacuum may refer to an environment exhibiting low-vacuum conditions (e.g., less than or equal to 100 kPa and greater than 100 Pa), medium-vacuum conditions (e.g., less than or equal to 100 Pa and greater than 0.1 Pa), high-vacuum conditions (e.g., less than or equal to 0.1 kPa and greater than 1 μPa), ultra-high-vacuum conditions (e.g., less than or equal to 1 μPa and greater than 1 nPa), or extreme-high-vacuum conditions (e.g., less than or equal to 1 nPa).

In this specification, the term “module” may refer to a self-contained unit or component that performs a specific function within a larger system. Additionally or alternatively, a module may refer to a subsystem that can be integrated with other subsystems to form a complete system. Further, a “transfer module” may refer to a module suitable or configured for transferring substrates between separate locations in a substrate processing environment. Additionally or alternatively, a transfer module may refer to a module suitable or configured to maintain a controlled environment to prevent contamination of substrates during transfer. In some embodiments, a transfer module may comprise fluid circulation means and/or filtering means to ensure the cleanliness of the environment inside the transfer module. In some embodiments, a transfer module may comprise one or more fluid circulation systems suitable or configured to circulate clean air or other gases within the transfer module to prevent substrate contamination. In some embodiments, a transfer module may comprise one or more filtering systems suitable or configured to remove particles, contaminants, and/or other impurities from the environment inside the transfer module. In some embodiments, a transfer module may comprise one or more robotic arms or other mechanical means suitable or configured for moving substrates between different locations within the transfer module. In some embodiments, a transfer module may be implemented as an Equipment Front End Module (EFEM).

Throughout this specification, a “vacuum chamber” may refer to a chamber suitable or configured for containing, transferring, and/or processing one or more substrates under vacuum. Additionally or alternatively, a “vacuum chamber” may refer to a chamber suitable or configured for performing one or more processes that require a vacuum environment, such as deposition, etching, and/or other semiconductor manufacturing processes. In some embodiments, a vacuum chamber may be implemented as a wafer transfer chamber. In some embodiments, a vacuum chamber may comprise a substrate transfer robot to enable substrate transfer between different components, such as a load lock arrangement and one or more substrate processing chambers. In some embodiments, a vacuum chamber may be fluidically coupled to one or more pumps for evacuating the vacuum chamber to achieve and maintain a vacuum environment. In some embodiments, a vacuum chamber may comprise one or more valves suitable or configured to control the flow of gases into and/or out of the vacuum chamber. In some embodiments, a vacuum chamber may comprise one or more sensors, such as one or more pressure sensors and/or one or more temperature sensors, to monitor and control the environmental conditions within the vacuum chamber.

In this disclosure, a “substrate” may refer to any underlying material or materials that may be used to form, or upon which, a device, a circuit, or a film may be formed. Additionally or alternatively, a substrate may refer to any material that provides a foundation for the fabrication of microelectronic, optoelectronic, or photonic devices. Additionally or alternatively, a substrate may refer to an object including a bulk material, such as silicon (e.g., single-crystal silicon), other Group IV materials, such as germanium, or compound semiconductor materials, such as GaAs, and optionally one or more layers overlying or underlying the bulk material and/or various structures, such as recesses, vias, lines, and the like formed within or on at least a portion of a layer of the substrate. In some embodiments, a substrate may comprise a semiconductor wafer. In some embodiments, a substrate may comprise a layered structure, including but not limited to, silicon-on-insulator (SOI) structure, wherein a thin layer of silicon is separated from a bulk silicon layer by an insulating layer, and epitaxial structures, wherein one or more epitaxial layers are grown on a bulk material layer.

Throughout this specification, a “substrate holder” may refer to a device or structure suitable or configured for holding one or more substrates in a load lock chamber. Additionally or alternatively, a substrate holder may refer to a device or structure suitable or configured for holding one or more substrates in a specific arrangement in a load lock chamber, for example, to facilitate substrate transfer and/or processing. In some embodiments, a substrate holder may be configured to hold a single substrate, whereas in other embodiments, a substrate holder may be configured to hold a plurality of substrates, e.g., two substrates, three substrates, four substrates, five substrates, and so forth. In other embodiments, a substrate holder may be configured to hold a plurality of substrates in a stacked arrangement at a plurality of substrate positions. In some embodiments, a substrate holder may be configured to hold substrates in a vertically stacked arrangement, wherein individual substrates extend laterally and face vertical directions in the operation position of a load lock arrangement; a laterally stacked arrangement, wherein individual substrates extend vertically and face lateral directions in the operation position of a load lock arrangement; or a slanted stacked arrangement, wherein individual substrates are arranged at an angle with respect to the vertical direction. In some embodiments, a substrate holder may comprise one or more mechanical components, such as clamps, brackets, or shelves, to secure the substrates in place. In some embodiments, a substrate holder may comprise one or more alignment features, such as grooves or notches, to ensure the precise positioning of the substrates. In some embodiments, automated substrate transfer to and from a substrate holder may be accomplished using one or more robotic arms or other mechanical substrate transfer means.

In this disclosure, a “heater” may refer to a device or apparatus suitable or configured to generate heat or thermal energy. Further, a “microwave heater” may refer to a heater suitable or configured for generating and transmitting microwave radiation to heat and/or process materials. Additionally or alternatively, a microwave heater may refer to a heater that generates heat through the use of microwave radiation. Additionally or alternatively, a microwave heater may refer to a heater that provides microwave radiation into a specific area or chamber to achieve a heating effect. Additionally or alternatively, microwave heater may refer to a heater suitable or configured for generating microwave radiation to desorb adsorbed moisture from one or more substrates. In some embodiments, a microwave heater may comprise a microwave source, such as a magnetron microwave source, solid-state microwave source, or the like. In some embodiments, a microwave heater may comprise a microwave mode stirrer. In some embodiments, a microwave heater may comprise a microwave waveguide. In some embodiments, a microwave heater may be configured to generate microwave radiation within one or more specific wavelength or frequency ranges. In some embodiments, a microwave heater may be configured to generate microwave radiation within a wavelength range from 1 cm to 30 cm and/or a frequency range from 1 GHz to 30 GHz. In some embodiments, a microwave heater may be configured to generate microwave radiation at specific output power levels. In some embodiments, a microwave heater may be configured to generate microwave radiation at an output power greater than or equal to 25 W and/or less than or equal to 10 kW. In some embodiments, a microwave heater may be operated in conjunction with a vacuum pump to evacuate a load lock chamber while generating microwave radiation for desorbing adsorbed moisture from the one or more substrates. Additionally or alternatively, a microwave heater may be used in conjunction with other components, such as fluid-tight windows formed of microwave-permeable materials, to ensure the efficient transmission of microwave radiation into a load lock chamber.

In this specification, a “chemical vapor deposition chamber” or “CVD chamber” may refer to a chamber, wherein one or more gaseous compounds decompose to deposit a layer onto a substrate. Further, a “cyclic chemical vapor deposition chamber” or “cyclic CVD chamber” may refer to a CVD chamber sequentially and/or cyclically providing precursors, and/or reactants, and/or active species to deposit a layer onto said substrate.

Throughout this specification, an “atomic layer deposition chamber” or “ALD chamber” may refer to a cyclic CVD chamber configured for purging between provision of precursors, and/or reactants, and/or active species. Typically, purging may be accomplished by flushing said ALD chamber or a process station thereof with an inert gas. Additionally or alternatively, an atomic layer deposition chamber may refer to a cyclic CVD chamber suitable for or configured to deposit a conformal layer, e.g., a layer with a step coverage (SC) of at least 95 %, or 99 %, or about 100 % for a feature with an aspect ratio (AR) of 3:1, or 5:1, or 10:1, onto a substrate.

Further, a “temporal atomic layer process” or “temporal ALD process” may refer to an ALD process, wherein the process of purging a process station comprises a temporal purging step during which provision of precursors, and/or reactants, and/or active species is discontinued. Additionally or alternatively, a “temporal atomic layer process” or “temporal ALD process” may refer to an ALD process, wherein a substrate onto which a layer is deposited is maintained immobile during deposition.

In some embodiments, the presently described methods, devices, and apparatuses may be useful in the fields of microfabrication and nanofabrication. In some embodiments, the presently described methods, devices, and apparatuses may be useful in the fields of microelectromechanical systems, microsystems, photonics, photovoltaics, display devices, and/or semiconductor manufacturing technology. In some embodiments, the presently described methods, devices, and apparatuses may be beneficial for handling and/or treatment of substrates, e.g., semiconductor wafers or solid-state devices, during their fabrication. In some embodiments, they may be applied to substrate processing apparatuses comprising a plurality of work-stations. In some embodiments, they may contribute to sustainable manufacturing practices in semiconductor production. In some embodiments, the presently described methods, devices, and apparatuses may be useful for increasing the throughput, and/or reducing the electricity consumption, and/or reducing the process gas consumption of modular substrate processing apparatuses and/or increasing the quality of films fabricated using substrate processing apparatuses.

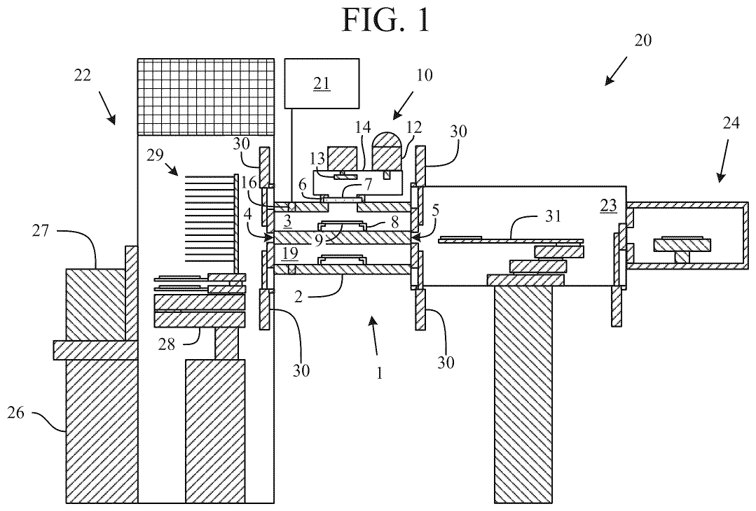

FIG. 1 schematically illustrates a substrate processing apparatus 20 provided with a load lock arrangement 1 according to an embodiment. Other embodiments may or may not be identical or similar to the embodiment of FIG. 1.

The load lock arrangement 1 of the embodiment of FIG. 1 comprises a load lock chamber body 2 that defines a load lock chamber 3. The substrate processing apparatus 20 of the embodiment of FIG. 1 comprises a transfer module 22 and a vacuum chamber 23, and the load lock chamber body 2 comprises a first face 4 configured for coupling to the transfer module 22 and a second face 5 configured for coupling to the vacuum chamber 23. The load lock arrangement 1 further comprises a substrate holder 8 for holding one or more substrates 9 in the load lock chamber 3 and a microwave heater 10 for desorbing adsorbed moisture from the one or more substrates 9. In some embodiments, such a load lock arrangement may increase the throughput, and/or reduce the electricity consumption, and/or reduce the process gas consumption of a substrate processing apparatus.

Even if not explicitly shown in FIG. 1, a substrate processing apparatus may generally comprise any suitable number of load lock arrangements according to the first aspect, for example, one or more load lock arrangements, two or more load lock arrangements, three or more load lock arrangements, and so forth. Any or all of such load lock arrangement may comprise any suitable number of microwave heaters, and any two individual microwave heaters of a load lock arrangement may be associated with separate load lock chambers or the same load lock chamber.

In the embodiment of FIG. 1, the load lock chamber body 2 comprises a viewport 6, and the microwave heater 10 is configured to transmit microwave radiation into the load lock chamber 3 via the viewport 6. In some embodiments, a microwave heater being configured to transmit microwave radiation into a load lock chamber via a viewport may facilitate desorbing adsorbed moisture from one or more substrates inside the load lock chamber with reduced modifications to existing load lock chamber designs, which may, in turn, facilitate retrofitting existing substrate processing apparatuses with load lock arrangement in accordance with this specification. Additionally or alternatively, in some embodiments a microwave heater being configured to transmit microwave radiation into a load lock chamber via a viewport may facilitate maintaining the cleanliness of the load lock chamber. In other embodiments, a microwave heater may or may not be configured to transmit microwave radiation into a load lock chamber via a viewport.

The viewport 6 of the embodiment of FIG. 1 comprises a fluid-tight window 7 formed of a microwave-permeable or microwave-transparent material, such as fused silica. In other embodiments, wherein load lock chamber body comprises a viewport and a microwave heater is configured to transmit microwave radiation into a load lock chamber via the viewport, the microwave radiation may be transferred in any suitable manner. In some such embodiments, a viewport may comprise a fluid-tight window formed of a microwave-permeable or microwave-transparent material, such as glass materials, such as borosilicate glass, quartz glass, or fused silica glass.

In the embodiment of FIG. 1, the viewport 6 is arranged above the load lock chamber 3, when the load lock arrangement 1 is operated. In some embodiments, wherein a load lock chamber body comprises a viewport and a microwave heater is configured to transmit microwave radiation into a load lock chamber via the viewport, the viewport being arranged above the load lock chamber in an operation position of a load lock arrangement may enable forming the load lock arrangement more compactly and/or increase the uniformity of desorbing adsorbed moisture from one or more substrates. In other embodiments, wherein a load lock chamber body comprises viewport(s) and a microwave heater is configured to transmit microwave radiation into a load lock chamber via the viewport(s), the viewport(s) may be arranged in any suitable manner(s) with respect to a load lock chamber, for example, above, below, and/or laterally adjacent to the load lock chamber, in an operation position of a load lock arrangement.

In the embodiment of FIG. 1, the microwave heater 10 comprises a magnetron microwave source 12. In some embodiments, a microwave heater comprising a magnetron microwave source may facilitate forming microwave radiation of suitable wavelengths for desorbing adsorbed moisture at higher output powers. Additionally or alternatively, in some embodiments a microwave heater comprising a magnetron microwave source may facilitate forming microwave radiation of suitable wavelengths for desorbing adsorbed moisture with a reduced substrate processing apparatus footprint. In other embodiments, a microwave heater may or may not comprise a magnetron microwave source. In other embodiments, a microwave heater may comprise any suitable type(s) of microwave source(s), e.g., solid-state microwave sources, in addition to or as an alternative to magnetron microwave source(s).

In the embodiment of FIG. 1, the microwave heater 10 comprises a microwave mode stirrer 13. In some embodiments, a microwave heater comprising a microwave mode stirrer may facilitate desorbing adsorbed moisture from the one or more substrates more uniformly and/or more rapidly. In other embodiments, a microwave heater may or may not comprise a microwave mode stirrer.

In the embodiment of FIG. 1, the microwave heater 10 comprises a microwave waveguide 14 for directing the microwave radiation from the magnetron microwave source 12 into the load lock chamber 3 via the viewport 6. In other embodiments, wherein a microwave heater comprises a microwave source, e.g., a magnetron microwave source, microwave radiation may be directed from the microwave source into the load lock chamber in any suitable manner, for example, via a viewport using a microwave waveguide.

The microwave heater 10 of the embodiment of FIG. 1 may be configured to generate microwave radiation with at least a wavelength of about 12 cm and/or a frequency of about 2.45 GHz. In other embodiments, a microwave heater may be configured to generate microwave radiation with any suitable wavelengths and/or frequencies. For example, in some embodiments a microwave heater may be configured to generate microwave radiation within a wavelength range from 1 cm to 30 cm, or from 3 cm to 25, or from 5 cm to 20 cm, or from 10 cm to 15 cm, or from 11 cm to 13 cm. In some embodiments, a microwave heater may be configured to generate microwave radiation within a frequency range from 1 GHz to 30 GHz, or from 1.2 GHz to 20 GHz, or from 1.5 GHz to 10 GHz, or from 1.7 GHz to 5 GHz, or from 2 GHz to 3 GHz. In some embodiments, a microwave heater being configured to generate microwave radiation within one or more of such wavelength ranges and/or such frequency ranges may facilitate desorbing adsorbed moisture from the one or more substrates more efficiently.

The microwave heater 10 of the embodiment of FIG. 1 may be configured to generate microwave radiation at a microwave output power of about 1000 W. In other embodiments, a microwave heater may be configured to generate microwave radiation at any suitable output power(s). For example, in some embodiments a microwave heater may be configured to generate microwave radiation at a microwave output power greater than or equal to 25 W, or to 50 W, or to 100 W, or to 200 W, or to 500 W, or to 1 kW and/or less than or equal to 2 kW, or to 3 kW, or to 4 kW, or to 5 kW, or to 10 kW. In some embodiments, a microwave heater being configured to generate microwave radiation at one or more of such microwave output power ranges may enable desorbing adsorbed moisture from one or more substrates efficiently without inadvertently damaging the one or more substrates. Additionally or alternatively, a microwave heater being configured to generate microwave radiation at one or more of such microwave output power ranges may enable desorbing adsorbed moisture from one or more substrates using simpler power supply arrangements.

In the embodiment of FIG. 1, the load lock chamber body 2 comprises one or more evacuation ports 16 for evacuation of the load lock chamber 3. In some embodiments, wherein a load lock arrangement comprises a microwave heater for desorbing adsorbed moisture from one or more substrates arranged in a load lock chamber defined by the load lock chamber body, the load lock chamber body further comprising one or more evacuation ports for evacuation of the load lock chamber may enable simultaneously desorbing adsorbed moisture from one or more substrates and evacuating the load lock chamber, which may, in turn, increase a throughput of a substrate processing apparatus provided with such a load lock arrangement. In other embodiments, a load lock chamber body may or may not comprise one or more evacuation ports for evacuation of a load lock chamber. For example, in some embodiments, a transfer module and/or a vacuum chamber may be configured for pressurization and/or evacuation to facilitate substrate transport using a load lock arrangement.

In the embodiment of FIG. 1, the load lock chamber body 2 further defines a second load lock chamber 19 for substrate transfer between the transfer module 22 and the vacuum chamber 23. The substrate processing apparatus 20 is configured to utilize the load lock chamber 3 for substrate transfer from the transfer module 22 to the vacuum chamber 23 and to utilize the second load lock chamber 19 for substrate transfer from the vacuum chamber 23 to the transfer module 22. In other embodiments, a load lock chamber body may define any suitable number of load lock chambers, for example, one or more load lock chambers, two or more load lock chambers, three or more load lock chambers, and so forth. In some embodiments, wherein a load lock arrangement comprises a microwave heater for desorbing adsorbed moisture from one or more substrates held in a load lock chamber, a load lock chamber body may define the load lock chamber, a second load lock chamber arranged below the load lock chamber in an operation position of a load lock arrangement, a third load lock chamber arranged laterally adjacent to the load lock chamber in the operation position, and a fourth load lock chamber arranged laterally adjacent to the second load lock chamber and below the third load lock chamber in the operation position. In some such embodiments, the load lock chamber, the second load lock chamber, the third load lock chamber, and the fourth load lock chamber may be arranged in a rectangular arrangement, when viewed from opposite a first face and/or from opposite a second face. Further, in some such embodiments, the load lock arrangement may comprise a second microwave heater for desorbing adsorbed moisture from substrate(s) held in the third load lock chamber.

The load lock arrangement 1 of the embodiment of FIG. 1 is configured to accommodate at most one substrate in the load lock chamber 3. In the embodiment of FIG. 1, the one or more substrates 9 to be held by the substrate holder 8 consists of the at most one substrate, and the load lock arrangement 1 is provided with the substrate holder 8 in the absence of other substrate holding means for holding further substrates in the load lock chamber 3. In some embodiments, a load lock arrangement being configured to accommodate at most one substrate in a load lock chamber may enable desorbing adsorbed moisture from the at most one substrate more rapidly and/or more uniformly, which may, in turn, increase a throughput of a substrate processing apparatus provided with such a load lock arrangement. In other embodiments, a load lock arrangement may or may not be configured to accommodate at most one substrate in a load lock chamber.

In the embodiment of FIG. 1, the substrate processing apparatus 20 comprises one or more load ports 26 configured for coupling to one or more substrate carriers 27, such as Front Opening Unified Pods (FOUPs) or the like. The one or more load ports 26 are coupled to the transfer module 22 for substrate transfer between the one or more substrate carriers 27 and the transfer module 22. In other embodiments, a substrate processing apparatus may or may not comprise such one or more load ports.

The transfer module 22 of the embodiment of FIG. 1 may be implemented as an Equipment Front End Module (EFEM). The transfer module 22 is configured to maintain a clean environment inside the transfer module 22 to avoid substrate contamination during substrate transfer via the transfer module 22. Although not depicted in FIG. 1, the transfer module 22 may comprise fluid circulation means and/or filtering means to ensure the cleanliness of the environment inside the transfer module 22. In other embodiments, a transfer module may be implemented in any suitable manner.

The transfer module 22 of the embodiment of FIG. 1 comprises one or more substrate cooling stages 29 to facilitate substrate cooling after substrate processing and a front-end substrate transfer robot 28 to enable substrate transfer between at least any of the one or more load ports 26, the one or more substrate cooling stages 29, and the load lock arrangement 1. In other embodiments, a transfer module may or may not comprise one or more substrate cooling stages. In such other embodiments, a transfer module may comprise any suitable substrate transfer means, for example, one or more front-end substrate transfer robots or the like to enable substrate transfer between any suitable substrate positions, for example, between at least any of one or more load ports, one or more substrate cooling stages and a load lock arrangement.

In the embodiment of FIG. 1, the load lock arrangement 1 comprises a plurality of gate valves 30 for providing fluid-tight sealing between the load lock chamber 3 and each of the transfer module 22 and the vacuum chamber 23 as well as between the second load lock chamber 19 and each of the transfer module 22 and the vacuum chamber 23. In other embodiments, a load lock arrangement may or may not comprise one or more gate valves suitable for and/or configured for providing fluid-tight sealing between a load lock chamber and one or more of a transfer module and a vacuum chamber and/or between a second load lock chamber and one or more of a transfer module and a vacuum chamber. In other embodiments, a load lock arrangement may or may not comprise any suitable number of gate valves for providing fluid-tight sealing for any one or more load lock chambers defined by a load lock chamber body.

In the embodiment of FIG. 1, the substrate processing apparatus 20 comprises a vacuum pump 21 fluidically coupled to the load lock chamber 3 for evacuation of the load lock chamber 3. The vacuum pump 21 of the embodiment of FIG. 1 is coupled to the one or more evacuation ports 16 and configured to evacuate the load lock chamber 3 while the microwave heater 10 generates microwave radiation for desorbing adsorbed moisture from the one or more substrates 9. In some embodiments, a substrate processing apparatus comprising a vacuum pump fluidically coupled to a load lock chamber for evacuation of the load lock chamber may facilitate simultaneously desorbing adsorbed moisture from one or more substrates and evacuating the load lock chamber, which may, in turn, increase a throughput of a substrate processing apparatus provided with such a vacuum pump. In other embodiments, a substrate processing apparatus may or may not comprise a vacuum pump fluidically coupled to the load lock chamber for evacuation of the load lock chamber. In embodiments, wherein a substrate processing apparatus comprises such a vacuum pump, the vacuum pump may be fluidically coupled to any suitable number of further chambers and/or modules for evacuation thereof.

In some embodiments, a substrate processing apparatus may be configured to affect evacuation the load lock chamber while a microwave heater generates microwave radiation for desorbing adsorbed moisture from one or more substrates. In some embodiments, a load lock chamber of a substrate processing apparatus may be fluidically coupled to an external evacuation source separate from the substrate processing apparatus for evacuation of a load lock chamber. In some such embodiments, the substrate processing apparatus may be configured to evacuate a load lock chamber using an external evacuation source while a microwave heater generates microwave radiation for desorbing adsorbed moisture from one or more substrates. In other embodiments, wherein a substrate processing apparatus comprises a vacuum pump fluidically coupled to a load lock chamber for evacuation of thereof, the vacuum pump may or may not be coupled to one or more evacuation ports, and/or the vacuum pump may or may not be configured to evacuate a load lock chamber while a microwave heater generates microwave radiation for desorbing adsorbed moisture from one or more substrates.

In the embodiment of FIG. 1, the substrate processing apparatus 20 comprises one or more deposition chambers 24 coupled to the vacuum chamber 23. Although a single deposition chamber of the one or more deposition chambers 24 is depicted in FIG. 1, the substrate processing apparatus 20 of the embodiment of FIG. 1 may comprise any suitable number, e.g., one or more, two or more, three or more, and so forth, of deposition chambers coupled to the vacuum chamber 23. In some embodiments, a load lock arrangement comprising a microwave heater for desorbing adsorbed moisture from one or more substrates may improve the quality and/or adhesion properties of films, e.g., electrically conductive and/or metallic films, deposited by one or more deposition chambers of a substrate processing apparatus. Further, even if not depicted in FIG. 1, a substrate processing apparatus may comprise any suitable number of one or more other types of substrate processing chambers, such as pre-cleaning chambers, pre-treatment chambers, etching chambers, post-treatment chambers, and the like, in addition to or as an alternative to one or more deposition chambers.

At least part of the one or more deposition chambers 24 of the embodiment of FIG. 1 may be implemented as chemical vapor deposition chambers, such as cyclic chemical vapor deposition chamber, e.g., atomic layer deposition chambers. In other embodiments, wherein a substrate processing apparatus comprises one or more deposition chambers coupled to a vacuum chamber, any deposition chamber of the one or more deposition chambers may be implemented in any suitable manner(s), for example, as chemical vapor deposition chambers, e.g., atomic layer deposition chambers; physical vapor deposition chambers, e.g., sputtering chambers and/or electron beam evaporation chambers; spin coating chambers; and/or spray pyrolysis chambers.

In the embodiment of FIG. 1, the vacuum chamber 23 may be implemented as a wafer transfer chamber. The vacuum chamber 23 comprises a back-end substrate transfer robot 31 to enable substrate transfer between at least any of the load lock arrangement 1 and the one or more deposition chambers 24. In other embodiments, a vacuum chamber may or may not comprise any suitable substrate transfer means, for example, one or more back-end substrate transfer robots or the like. In some embodiments, wherein a substrate processing apparatus comprises a vacuum chamber coupled to a load lock arrangement, the vacuum chamber may be implemented as a substrate processing chamber, such as a deposition chamber, an etching chamber, or the like.

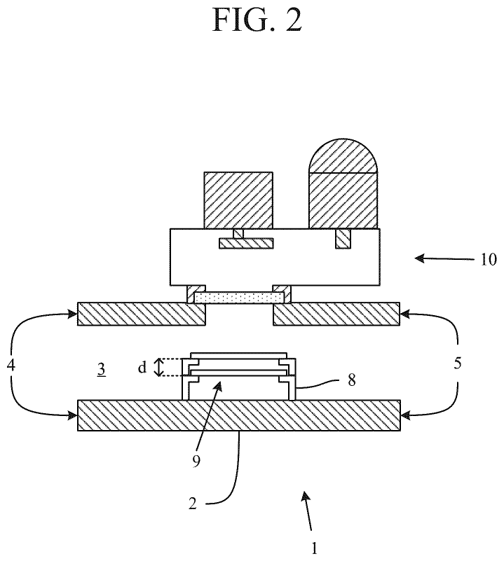

FIG. 2 schematically illustrates a load lock arrangement 1 according to an embodiment. Even if not depicted in FIG. 2, the load lock arrangement 1 of the embodiment of FIG. 2 may comprise any features of load lock arrangements disclosed within this specification. Other embodiments may or may not be identical or similar to the embodiment of FIG. 2.

The load lock arrangement 1 of the embodiment of FIG. 2 comprises a load lock chamber body 2, which defines a load lock chamber 3 and comprises a first face 4 configured for coupling to a transfer module and a second face 5 configured for coupling to a vacuum chamber. The load lock arrangement 1 further comprises a substrate holder 8 for holding one or more substrates 9 in the load lock chamber 3 and a microwave heater 10 for desorbing adsorbed moisture from the one or more substrates 9.

In the embodiment of FIG. 2, The substrate holder 8 is configured to hold the one or more substrates 9 in a stacked arrangement at a plurality of substrate positions, maintaining a minimum distance d between adjacent substrate positions of the plurality of substrate positions of about 6 cm. In other embodiments, wherein a substrate holder is configured to hold one or more substrates in a stacked arrangement at a plurality of substrate positions, the substrate holder may be configured to maintain any suitable minimum distance, for example, a minimum distance of at least 1 cm, or at least 2 cm, or at least, 3 cm, or at least 4 cm, or at least 5 cm, or at least 6 cm, or at least 7 cm, or at least 8 cm, or at least 9 cm, or at least 10 cm, or at least 11 cm, or at least 12 cm, between adjacent substrate positions of the plurality of substrate positions. In some embodiments, wherein a substrate holder is configured to hold one or more substrates in a stacked arrangement at a plurality of substrate positions, maintaining a sufficient minimum distance between adjacent substrate positions of the plurality of substrate positions may increase throughput and/or uniformity in desorbing adsorbed moisture from the one or more substrates.

The substrate holder 8 of the embodiment of FIG. 2 is configured to hold the one or more substrates 9 in a vertically stacked arrangement, wherein individual substrates of the one or more substrates 9 extend laterally and face vertical directions in an operation position of the load lock arrangement 1. In some embodiments, a substrate holder being configured to hold one or more substrates in a vertically stacked arrangement in an operation position of a load lock arrangement may enable substrate transfer without substrate tilting, which may, in turn, increase a throughput of a substrate processing apparatus. In other embodiments, wherein a substrate holder is configured to hold one or more substrates in a stacked arrangement at a plurality of substrate positions, the substrate holder may be configured to hold one or more substrates in any suitable stacked arrangement, for example, a vertically stacked arrangement; or a laterally stacked arrangement, wherein individual substrates of the one or more substrates extend vertically and face lateral directions in an operation position of the load lock arrangement; or a slanted stacked arrangement, wherein individual substrates of the one or more substrates are arranged in a slanted arrangement with respect to the vertical direction in an operation position of the load lock arrangement.

The load lock arrangement 1 of the embodiment of FIG. 2 is configured to accommodate at most two substrates in the load lock chamber 3. In the embodiment of FIG. 1, the one or more substrates 9 to be held by the substrate holder 8 consists of the at most two substrates, and the load lock arrangement 1 is provided with the substrate holder 8 in the absence of other substrate holding means for holding further substrates in the load lock chamber 3. In some embodiments, a load lock arrangement being configured to accommodate at most two substrates in a load lock chamber may enable desorbing adsorbed moisture from the at most two substrates more rapidly and/or more uniformly, which may, in turn, increase a throughput of a substrate processing apparatus provided with such a load lock arrangement. In other embodiments, a load lock arrangement may or may not be configured to accommodate at most two substrates in a load lock chamber.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A load lock arrangement, comprising:
a load lock chamber body, defining a load lock chamber and comprising a first face configured for coupling to a transfer module and a second face configured for coupling to a vacuum chamber; and
a substrate holder for holding one or more substrates in the load lock chamber;
wherein the load lock arrangement comprises a microwave heater for desorbing adsorbed moisture from the one or more substrates.

2. A load lock arrangement according to claim 1, wherein the load lock chamber body comprises a viewport, and the microwave heater is configured to transmit microwave radiation into the load lock chamber via the viewport.

3. A load lock arrangement according to claim 1, wherein the microwave heater comprises a magnetron microwave source.

4. A load lock arrangement according to claim 1, wherein the microwave heater comprises a microwave mode stirrer.

5. A load lock according to claim 1, wherein the microwave heater is configured to generate microwave radiation within a wavelength range from 1 cm to 30 cm, or from 3 cm to 25, or from 5 cm to 20 cm, or from 10 cm to 15 cm, or from 11 cm to 13 cm.

6. A load lock arrangement according to claim 1, wherein the microwave heater is configured to generate microwave radiation at a microwave output power greater than or equal to 25 W, or to 50 W, or to 100 W, or to 200 W, or to 500 W, or to 1 kW and/or less than or equal to 2 kW, or to 3 kW, or to 4 kW, or to 5 kW, or to 10 kW.

7. A load lock arrangement according to claim 1, wherein the load lock chamber body comprises one or more evacuation ports for evacuation of the load lock chamber.

8. A load lock arrangement according to claim 1, wherein the load lock chamber body further defines a second load lock chamber for substrate transfer between the transfer module and the vacuum chamber.

9. A load lock arrangement according to claim 1, wherein the substrate holder is configured to hold the one or more substrates in a stacked arrangement at a plurality of substrate positions, maintaining a minimum distance between adjacent substrate positions of the plurality of substrate positions of at least 1 cm, or at least 2 cm, or at least, 3 cm, or at least 4 cm, or at least 5 cm, or at least 6 cm, or at least 7 cm, or at least 8 cm, or at least 9 cm, or at least 10 cm, or at least 11 cm, or at least 12 cm.

10. A load lock arrangement according to claim 1, wherein the load lock arrangement is configured to accommodate at most two substrates in the load lock chamber.

11. A load lock arrangement according to claim 1, wherein the load lock arrangement is configured to accommodate at most one substrate in the load lock chamber.

12. A substrate processing apparatus, comprising a load lock arrangement according to claim 1.

13. A substrate processing apparatus according to claim 12, wherein the substrate processing apparatus comprises a transfer module coupled to the load lock arrangement.

14. A substrate processing apparatus according to claim 12, wherein the substrate processing apparatus comprises a vacuum chamber coupled to the load lock arrangement.

15. A substrate processing apparatus according to claim 12, wherein the substrate processing apparatus comprises a vacuum pump fluidically coupled to the load lock chamber for evacuation thereof.

16. A substrate processing apparatus according to claim 12, wherein the substrate processing apparatus comprises one or more deposition chambers coupled to the vacuum chamber.
